(19) United States
(12) Patent Application Publication
(10) Pub. No.: US 2014/0340593 A1
(43) Pub. Date: Nov. 20, 2014

(54) ELECTRONIC COMPONENT, TOUCH PANEL AND LIQUID CRYSTAL DISPLAY DEVICE USING THE SAME

(71) Applicant: Japan Display Inc., Minato-ku (JP)

(72) Inventors: Yuji SATO, Minato-ku (JP); Yoshikazu YOMOGIHARA, Minato-ku (JP)

(73) Assignee: Japan Display Inc., Minato-ku (JP)

(21) Appl. No.: 14/264,239

(22) Filed: Apr. 29, 2014

(30) Foreign Application Priority Data
May 14, 2013 (JP) 2013-102001

(51) Int. Cl. H05K 1/11; H05K 1/02; H05K 3/10; G02F 1/1333

(52) U.S. Cl. CPC H05K 1/118; G02F 1/13338; H05K 1/0266; H05K 3/10
USPC 349/12; 174/255; 29/850

(57) ABSTRACT

An electronic component includes a substrate, a shielding layer formed on the substrate and a wiring substrate connected to the substrate. A pad group is formed on an overlap region on which the wiring substrate is arranged on the substrate. A first alignment pattern is formed on the substrate and extending to outside of the overlap region beyond a peripheral portion of the overlap region. A second alignment pattern is formed on the substrate and extending to outside of the overlap region beyond the peripheral portion of the overlap region. The pad group, the first and second alignment patterns are formed on the shielding layer. The first alignment pattern extends in a different direction from the direction of the second alignment pattern.

### CROSS-REFERENCE TO RELATED APPLICATION

This application is based upon and claims the benefit of priority from prior Japanese Patent Application No. 2013-102001, filed May 14, 2013, the entire contents of which are incorporated herein by reference.

### FIELD

Embodiments described herein relate generally to an electronic component, a touch panel and a liquid crystal display device using the same.

### BACKGROUND

Needs of a touch panel as an input interface in mobile terminals, such as a mobile phone, have been expanding by optical feature that haze is small and transmissivity is high, and wide application such as multi-touch correspondence. There is a capacitive sensor as one of position detection methods of the touch panel.

The touch panel using the electric capacitive sensor, for example, is attached to a display surface of a liquid crystal display panel. The touch panel is equipped with a glass substrate, a detection electrode formed of ITO (Indium Tin Oxide) on the glass substrate. The glass substrate of the touch panel is attached on the display surface of the liquid crystal display panel by adhesives. A detection electrode side of the touch panel is covered with a decorative plate. The decorative plate is attached on the touch panel by adhesives.

In the touch panel, when operator's fingers, etc., contact on the surface of the decorative plate to input data, the electrostatic capacitance of the detection electrode changes near the input position. For this reason, the detection electrode can detect the input data by detecting the change of electrostatic capacitance as voltage change. The display device includes a liquid crystal display panel, a touch panel and a decorative plate.

A signal (voltage) is applied to the touch panel through a flexible wiring substrate. Generally, the flexible wiring substrate is not transparent. Therefore, there is a possibility that the flexible wiring substrate may be fixed to the touch panel at a shifted position from the designed position. Accordingly, the touch panel (electronic device) which can secure a stable electrical connection with the flexible wiring substrate is requested.

### BRIEF DESCRIPTION OF THE DRAWINGS

The accompanying drawings, which are incorporated in and constitute a portion of the specification, illustrate embodiments of the invention, and together with the general description given above and the detailed description of the embodiments given below, serve to explain the principles of the invention.

FIG. 1 is a cross-sectional view schematically showing a structure of a liquid crystal display device according to one embodiment.

FIG. 2 is a plan view schematically showing the liquid crystal display panel shown in FIG. 1.

FIG. 3 is a cross-sectional view schematically showing the structure of the liquid crystal display panel taken along line A-A shown in FIG. 2.

FIG. 4 is a plan view schematically showing a touch panel shown in FIG. 1.

FIG. 5 is an enlarged plan view showing a portion of the touch panel, specifically a sensor module.

FIG. 6 is a cross-sectional view showing a portion of the sensor module taken along line B-B in FIG. 5.

FIG. 7 is an enlarged plan view showing a portion of the touch panel, specifically a pad.

FIG. 8 is a cross-sectional view showing a pad of the touch panel taken along line C-C in FIG. 7.

FIG. 9 is a figure showing the pad of the touch panel taken along line D-D in FIG. 7.

FIG. 10 is an enlarged plan view showing portions of the touch panel and the FPC (Flexible Printed Circuit) and a state in which the FPC is connected with the touch panel.

FIG. 11 is an enlarged plan view schematically showing the touch panel shown in FIG. 10.

FIG. 12 is an enlarged plan view schematically showing the FPC shown in FIG. 10.

FIG. 13 is a schematic view showing a state where a camera is taking picture alignment patterns of the FPC and the touch panel.

FIG. 14 is an enlarged plan view schematically showing a modification of pad groups of the touch panel.

FIG. 15 is a cross-sectional view showing a portion of the touch panel, specifically the pad taken along line E-E in FIG. 14.

FIG. 16 is a cross-sectional view showing the pad of the touch panel taken along line E-F in FIG. 14.

FIG. 17 is a schematic cross-sectional view showing a modification of the liquid crystal display device according to the embodiment.

### DETAILED DESCRIPTION

An electronic component, a touch panel and a liquid crystal display device using the same, according to an exemplary embodiment of the present invention will now be described with reference to the accompanying drawings wherein the same or like reference numerals designate the same or corresponding portions throughout the several views.

According to one embodiment, an electronic component includes: a substrate; a shielding layer formed on the substrate; a wiring substrate connected to the substrate; a pad group formed on an overlap region on which the wiring substrate is arranged on the substrate; a first alignment pattern formed on the substrate and extending to outside of the overlap region beyond a peripheral portion of the overlap region; a second alignment pattern formed on the substrate and extending to outside of the overlap region beyond the peripheral portion of the overlap region; wherein the pad group, the first and second alignment patterns are formed on the shielding layer, and the first alignment pattern extends in a different direction from the direction of the second alignment pattern.

According to other embodiment, a touch panel includes: an insulating substrate including an input area and a peripheral area located adjacent to the input area; a shielding layer formed on the peripheral area; a wiring substrate connected to the substrate; an input device arranged in the input area and including a plurality of detection electrodes arranged in first and second directions orthogonally crossing each other in a matrix shape; a pad group formed on an overlap region in the peripheral area on which the wiring substrate is arranged, and connected with the detection electrodes through connection wirings; an adhesive material to attach the wiring substrate and the insulating substrate; a first alignment pattern formed on the insulating substrate and extending to outside of the overlap region from the peripheral portion of the overlap region; a second alignment pattern formed on the insulating substrate and extending to outside of the overlap region from the peripheral portion of the overlap region; and a third alignment pattern formed on the wiring substrate, wherein the pad group, the first and second alignment patterns are formed on the shielding layer, the first alignment pattern extends in a different direction from the direction of the second alignment pattern, and the third alignment pattern is arranged on the first and second alignment patterns.

According to other embodiment, a liquid crystal display device includes: a touch panel including; an insulating substrate including an input area and a peripheral area located adjacent to the input area; a shielding layer formed on the peripheral area; a wiring substrate connected to the substrate; an input device arranged in the input area and including a plurality of detection electrodes arranged in first and second directions orthogonally crossing each other in a matrix shape; a pad group formed on an overlap region in the peripheral area on which the wiring substrate is arranged, and connected with the detection electrodes through connection wirings; an adhesive material to attach the wiring substrate and the insulating substrate, a first alignment pattern formed on the insulating substrate and extending to outside of the overlap region beyond the peripheral portion of the overlap region; a second alignment pattern formed on the insulating substrate and extending to outside of the overlap region beyond the peripheral portion of the overlap region; and a third alignment pattern formed on the wiring substrate, wherein the pad group, the first and second alignment patterns are formed on the shielding layer, the first alignment pattern extends in a different direction from the direction of the second alignment pattern, and the third alignment pattern is arranged on the first and second alignment patterns, a liquid crystal display panel including a display area arranged facing the input area of the touch panel, wherein the touch panel is attached to the liquid crystal panel using an adhesive material.

According to other embodiment, a method of manufacturing a touch panel includes the steps: preparing an insulating substrate including an input area and a peripheral area located adjacent to the input area; forming a shielding layer formed on the peripheral area; forming an input device arranged in the input area and including a plurality of detection electrodes arranged in first and second directions orthogonally crossing each other in a matrix shape; forming a pad group on an overlap region in the peripheral area on which a wiring substrate is arranged; the pad group being connected with the detection electrodes through connection wirings; forming a first alignment pattern on the insulating substrate and extending to outside of the overlap region beyond the peripheral portion of the overlap region; forming a second alignment pattern on the insulating substrate and extending to outside of the overlap region beyond the peripheral portion of the overlap region; forming a third alignment pattern on the wiring substrate; performing alignment of the first and second alignment patterns and the third alignment pattern by visually adjusting shift among the first second and third alignment patterns from above the first and second alignment patterns; attaching the insulating substrate to the wiring substrate by overlapping the first and second alignment patterns with the third alignment pattern using an adhesive, wherein the first alignment pattern extends in a different direction from the direction of the second alignment pattern, and the third alignment pattern is arranged on the first and second alignment patterns.

In this embodiment, electronic components are implemented in the touch panel. The liquid crystal display device is equipped with the touch panel.

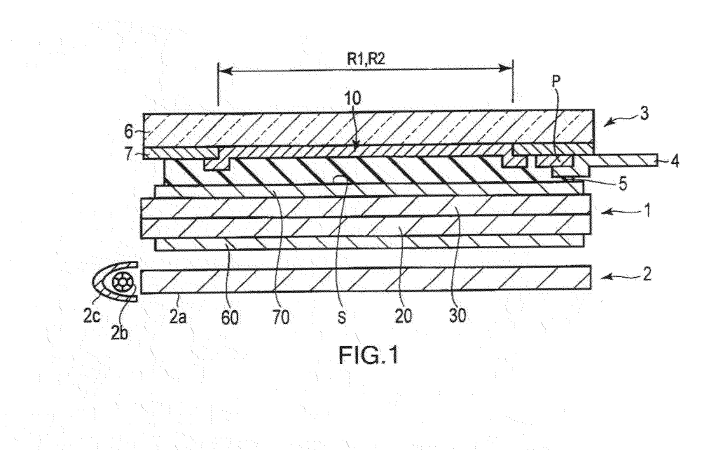

As shown in FIG. 1, the liquid crystal display device is equipped with a liquid crystal display panel 1 as a display panel having a display surface which displays images, a back light unit 2, a touch panel 3, a FPC (flexible printed circuits) 4 as a wiring substrate, and adhesive materials 5. To be mentioned later, the touch panel 3 is equipped with function as a decorative plate and the touch panel.

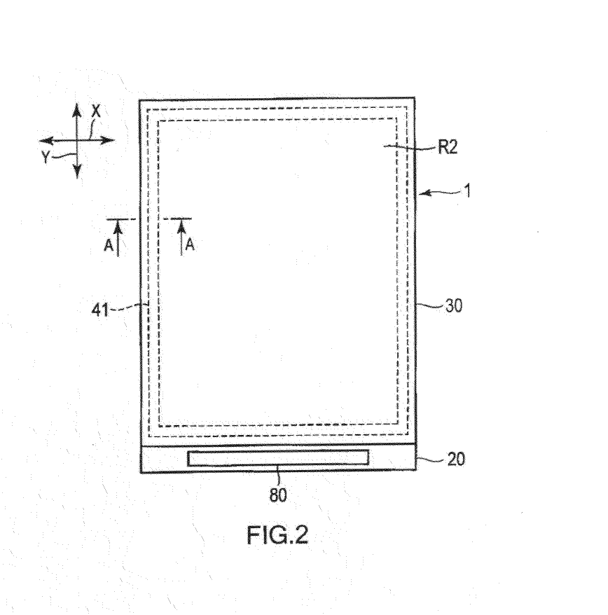

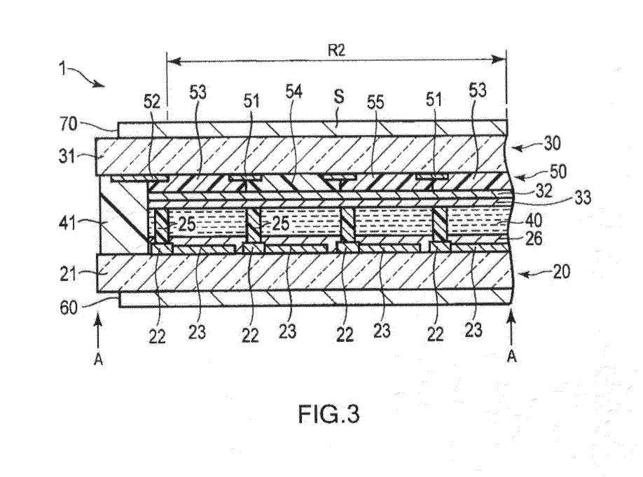

As shown in FIGS. 1, 2 and 3, the liquid crystal display panel 1 is equipped with an array substrate 20, a counter substrate 30, a liquid crystal layer 40, a first polarization portion 60, and a second polarization portion 70 with a display surface S. The array substrate 20 and the counter substrate 30 are formed in a rectangular shape, respectively. The array substrate 20 is formed in a larger size than the counter substrate 30.

The array substrate 20 and the counter substrate 30 are arranged so that three sides of the substrates may almost overlap, respectively. In one remaining side of the array substrate 20, the array substrate 20 extends to outside of the counter substrate 30. In more detail, the array substrate 20 and the counter substrate 30 are arranged so that they may almost overlap in the first direction X. In a second direction Y orthogonally crossing the first direction X, the array substrate 20 extends to outside of the counter substrate 30. The liquid crystal display panel 1 includes a display area R2 in a rectangular shape which overlaps with the array substrate 20 and the counter substrate 30.

The array substrate 20 includes a rectangular glass substrate 21 as a transparent insulating substrate. A driving circuit 80 is mounted on the glass substrate 21 on a portion away from the counter substrate 30. In the display area R2, a plurality of pixels is arranged on the glass substrate 21. The pixels are arranged in the shape of a matrix along with the first direction X and the second direction Y. In the display area R2, a plurality of signal lines and scanning lines which are not illustrated are formed in the shape of a lattice on the glass substrate 21.

In the circumference of an intersection portion of the signal line with the scanning line, TFT (Thin Film Transistor) 22 is provided as a switching element, for example. On the glass substrate 21, a plurality of pixel electrodes 23 are formed in the shape of a matrix. The pixel electrode 23 is formed of transparent electric conductive materials, such as ITO (Indium Tin Oxide). The pixel includes TFT22 and the pixel electrode 23 electrically connected with the TFT, respectively.

On the glass substrate 21 in which TFT22 and the pixel electrode 23 are formed, a plurality of pillar-shaped spacers 25 are formed. An alignment film 26 is formed on the glass substrate 21 and the pixel electrode 23.

The counter substrate 30 includes a rectangular glass substrate 31 as a transparent insulating substrate. In the display area R2, a color filter 50 is formed on the glass substrate 31. The color filter 50 has a shielding portion 51, a circumference shielding portion 52, and a plurality of colored layers such as a red colored layer 53, a green colored layer 54, and a blue colored layer 55.

The shielding portion 51 is formed in the shape of a lattice so as to overlap with the signal line and the scanning line. The circumference shielding portion 52 is formed in the shape of a rectangular frame in all over the circumference of the display area R2. The circumference shielding portion 52 contributes to shield the light which leaks to the outside of the display region R2.

The colored layers 53, 54, and 55 are formed on the glass substrate 31, the shielding portion 51, and the circumference shielding portion 52. The colored layers 53, 54, and 55 are arranged adjoining in the first direction X alternately. The colored layers 53, 54, and 55 are formed in the shape of a stripe, respectively, extending in the second direction Y, and overlap with the pixel located in a line in the second direction Y. The peripheral portions of the colored layers 53, 54, and 55 overlap with the shielding portion 51 and the circumference shielding portion 52. On the color filter 50, a counter electrode 32 is formed of transparent electric conductive materials, such as ITO. An alignment film 33 is formed on the counter electrode 32.

The array substrate 20 and the counter substrate 30 are arranged with a predetermined gap therebetween by a pillar-shaped spacer 25 so as to counter each other. The array substrate 20 and the counter substrate 30 are attached each other by a seal material 41 provided in the peripheral portions of both substrates, which are outside of the display area R2. The liquid crystal layer 40 is held between the array substrate 20 and the counter substrate 30, and surrounded by the seal material 41.

The first polarization portion 60 is arranged on the external surface of the glass substrate 21. The second polarization portion 70 is arranged on the external surface of the glass substrate 31. As mentioned above, the display surface S is formed in the external surface of the second polarization portion 70.

As shown in FIG. 1, a back light unit 2 is arranged on the external surface side of the array substrate 20. The back light unit 2 includes a light guide plate 2a arranged so as to face the first polarization portion 60, and a light source 2b and a light reflector 2c arranged so as to face an end side of the light guide plate 2a.

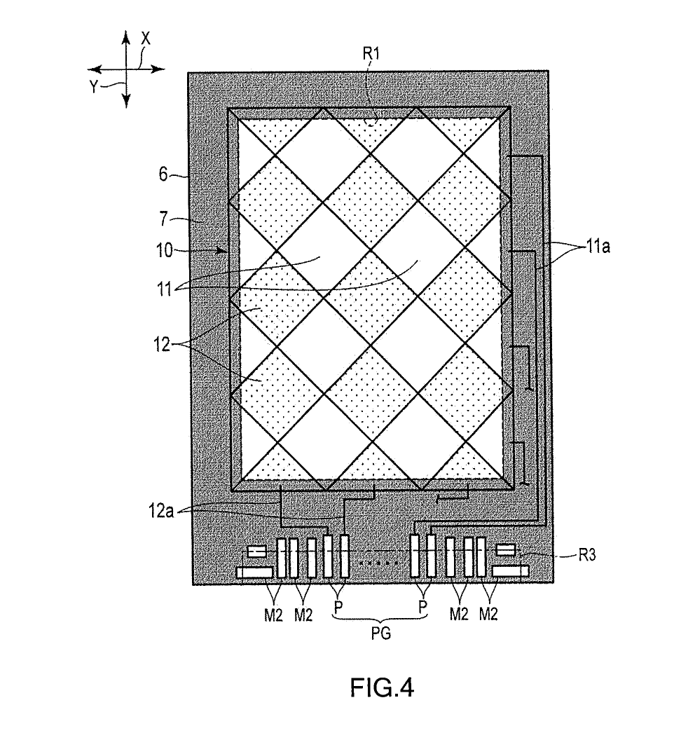

As shown in FIG. 1 and FIG. 4, the touch panel 3 is equipped with a transparent insulating substrate 6, a shielding layer 7 as a shielding portion, a sensor module 10, a pad group PG, and an alignment pattern M2. The touch panel 3 includes an input area R1. Herein, the input area R1 overlaps with the display area R2.

The insulating substrate 6 faces the display surface S of the liquid crystal display panel 1. The insulating substrate 6 is formed in the shape of a rectangle having a flat surface. The insulating substrate 6 ornaments the display surface S side of the liquid crystal display panel 1, and decorates appearance of the liquid crystal display device. For this reason, the insulating substrate 6 is formed with a glass substrate and functions as a decorative plate.

The insulating substrate 6 may be formed of transparent insulating material, such as an acrylic resin without being limited to the glass substrate. For example, when forming the insulating substrate 6 using the acrylic resin, weight saving and cost reduction can be attained compared with the case in which the glass substrate is used. Moreover, the insulating substrate 6 protects the sensor module 10 mechanically by preventing breakage of the sensor module 10, and also the sensor module 10 chemically by preventing invasion of humidity to the sensor module 10.

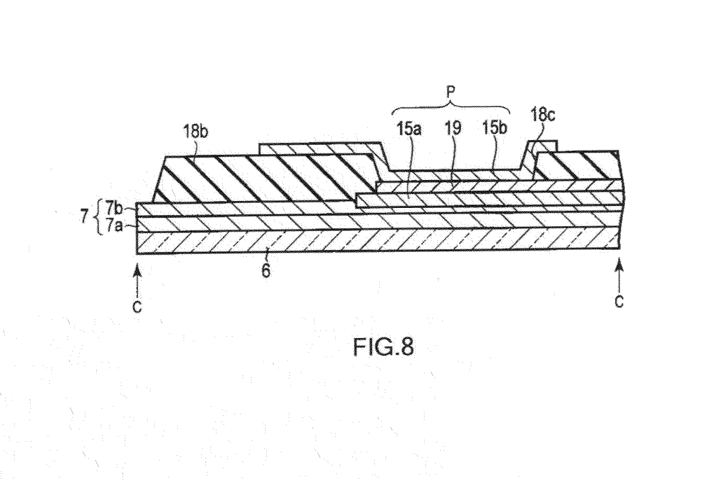

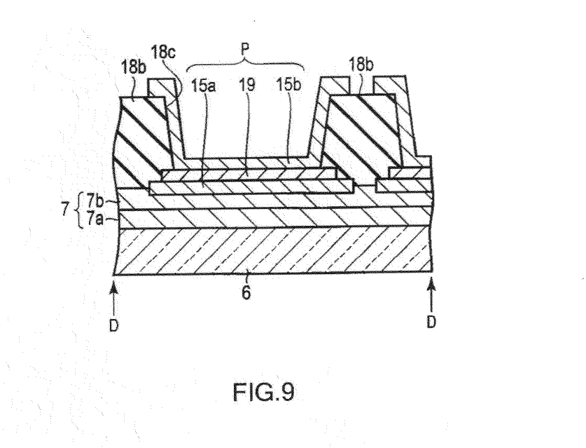

The shielding layer 7 is formed by laminating a first shielding layer 7a and a second shielding layer 7b (FIG. 8 and FIG. 9). The shielding layer 7 is formed in the shape of a rectangular frame on the back of the insulating substrate 6, and surrounds the input area R1. The shielding layer 7 is formed in a black frame and contributes to shield the leaked light from the input area R1 to outside.

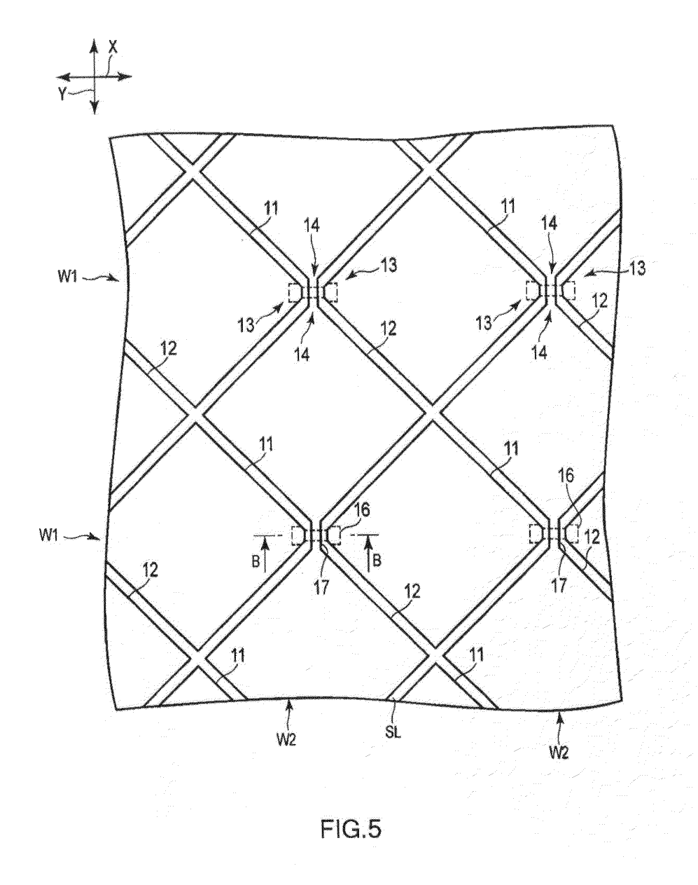

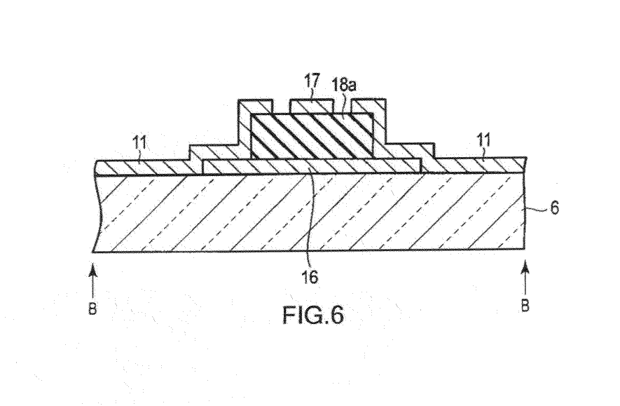

As shown in FIGS. 1, 4, 5, and 6, the sensor module 10 is formed on the back of the insulating substrate 6 in which the shielding layer 7 is formed, and faces the display surface S of the liquid crystal display panel 1. The sensor module 10 uses a capacitive sensor as a position detection method. The sensor module 10 detects input information (input position coordinate information) by input means from the surface side of the insulating substrate 6.

The sensor module 10 includes a plurality of first detection electrodes 11 and second detection electrodes 12 as the detection electrode by which electrostatic capacitance changes with the inputs (contact to the surface of the insulating substrate 6) by input means, such as an operator's finger and a conductor. The electrode pattern of the sensor module 10 includes a plurality of connection wirings 16 and 17 besides the plurality of first detection electrodes 11 and second detection electrodes 12.

The first detection electrode 11, the second detection electrode 12, the connection wiring 16, and the connection wiring 17 are arranged on the back of the insulating substrate 6 in the input area R1, and formed, for example, of ITO (Indium Tin Oxide) as a transparent electric conductive material. Herein, the connection wiring 16 is formed by a first manufacturing process using ITO. On the other hand, the first detection electrode 11, the second detection electrode 12, and the connection wiring 17 are formed by a second manufacturing process using ITO.

The plurality of first detection electrodes 11 is arranged in the first direction X and the second direction Y. The first detection electrode 11 is formed in a square shape with a diagonal line in the first direction X and the second direction Y, respectively. The first detection electrodes 11 include first angle portions which counter each other along the first direction X. The adjacent first angle portions in the first direction X are connected.

In this embodiment, the first angle portion of the first rectangular detection electrode 11 is crushed and forms a first narrow side 13. For this reason, the first detection electrode 11 is formed in a hexagon shape with the first narrow end 13. Moreover, the adjacent first narrow ends 13 are connected through a connection wiring 16. The connection wiring 16 is formed in the shape of an island on the insulating substrate 6.

The plurality of first detection electrodes 11 and connection wirings 16 connected mutually form a first wiring W1 that extends in the first direction X. The plurality of first wirings W1 is arranged in the second direction Y. As mentioned above, the plurality of the first detection electrodes 11 and connection wirings 16 are formed by different manufacturing processes each other. By detecting change of electrostatic capacitance using the first wiring W1, X coordinates of the input position are detectable by input means.

The plurality of second detection electrodes 12 is arranged in the first direction X and the second direction Y with a space between the second detection electrodes 12 and the first detection electrodes 11. The second detection electrode 12 is formed in a square shape with a diagonal line in the first direction X and the second direction Y, respectively. The adjacent second detection electrodes 12 include second angle portions which counter each other along the second direction Y. The adjacent second angle portions are connected in the second direction Y.

In this embodiment, the second angle portion of the second rectangular detection electrode 12 is crushed, and includes a second narrow end 14. For this reason, the second detection electrode 12 is formed in a hexagon shape with the second narrow end 14. Moreover, adjacent second short ends 14 are connected through a connection wiring 17. The connection wiring 17 is arranged in the shape of an island on the insulating substrate 6.

The plurality of second detection electrodes 12 and connection wirings 17 connected mutually form a second wiring W2 that extends in the second direction Y. The plurality of second wirings W2 is arranged in the first direction X. The plurality of second detection electrodes 12 and connection wirings 17 in the second wiring W2 are simultaneously formed by the same manufacturing process. By detecting change of electrostatic capacitance using the second wiring W2, Y coordinates of the input position are detectable by the input means.

A slit SL in a lattice shape is formed between the first detection electrode 11 and the second detection electrode 12. Thereby, electric insulation distance is secured between the first detection electrode 11 and the second detection electrode 12. On the insulating substrate 6, a plurality of insulating layers 18a is arranged in the shape of an island. The plurality of insulating layers 18a is arranged at a plurality of intersection portions in which the plurality of first wirings W1 and second wiring W2 cross on the insulating substrate 6 so as to interposing the insulating layer 18a therebetween. The insulating layer 18a prevents short circuit between the first wiring W1 and the second wiring W2. In this embodiment, the insulating layer 18a is formed of an organic insulating material.

The connection wiring 16 faces the connection wiring 17 interposing the insulating layer 18a therebetween. Herein, the connection wiring 16 is located under the insulating layer 18a, and the connection wiring 17 is located above the insulating layer 18a. Therefore, the connection wiring 17 can be said to be a bridge wiring.

In the outside of the input area R1, a plurality of wirings 11a and wirings 12a are arranged on the insulating substrate 6 (shielding layer 7). One end portion of respective wirings 11a is connected to the first wiring W1 (the first detection electrode 11) located in the outside of the input area R1, and the other end portion is connected to the pad “p” of a pad group PG. One end portion of the respective wirings 12a is connected to the second wiring W2 (the second detection electrode 12) located in the outside of the input area R1, and the other end portion is connected to the pad “p” of the pad group PG. For this reason, the information on the X coordinates and the Y coordinates of the input position, which the sensor module 10 detects by the input means, is outputted to the plurality of pads “p” through the plurality of wirings 11a and 12a.

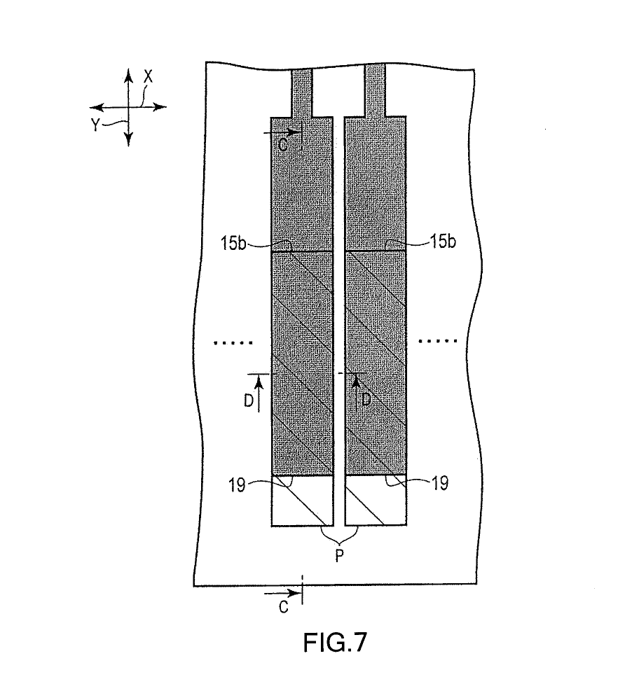

As shown in FIGS. 1, 4, and FIGS. 7, 8, 9, the pad group PG is arranged in an overlap area R3 located in the outside of the input area R1. The overlap area R3 is an area in which a connection area of the FPC4 is attached to the insulating substrate 6. The overlap area R3 is provided in one side of the insulating substrate 6. The pad group PG is equivalent to an outer lead bonding pad group. The pad group PG is formed on the shielding layer 7.

The plurality of pads “p” of the pad group PG extends in the second direction Y, and is arranged in the first direction X mutually keeping an interval between the adjacent pads. Herein, the plurality of pads “p” is arranged at equal interval in the first direction X. The pad “p” is formed on the second shielding layer 7b. The pad “p” is formed with a metal pattern, a transparent electric conductive pattern, or their composite layers. In this embodiment, the pad “p” is formed with the composite layer of the metal pattern and the transparent electric conductive pattern.

In detail, the pad “p” includes a lower transparent electric conductive layer 15a as a transparent electric conductive pattern, a metal layer 19 as a metal pattern, an insulating layer 18b, and an upper transparent electric conductive layer 15b as a transparent electric conductive pattern.

The lower transparent electric conductive layer 15a is formed on the second shielding layer 7b. The lower transparent electric conductive layer 15a is formed in the shape of a rectangle. The lower transparent electric conductive layer 15a can be formed using ITO, etc. In this embodiment, since the connection wiring 16 is formed using ITO, the lower transparent electric conductive layer 15a can be formed simultaneously with the connection wiring 16 using ITO.

Moreover, the lower transparent electric conductive layer 15a can be used as a seat layer for the metal layer 19. Accordingly, adhesion nature of the metal layer 19 can be raised. In addition, the adhesion strength of the metal layer 19 to the lower transparent electric conductive layer 15a is stronger than the adhesion strength of the metal layer 19 to the second

The metal layer 19 is formed on the lower layer transparent electric conductive layer 15a, and connected to the lower layer transparent electric conductive layer 15a. The metal layer 19 is formed in the shape of a rectangle. The metal layer 19 is formed using metal materials, such as MAM. Herein, MAM is a metal layer of three-layer structure in an abbreviated name of Mo (molybdenum)/Al (aluminum)/Mo. The above-mentioned aluminum layer may be formed of aluminum alloys, such as Al—Nd (aluminum neodymium system alloy). In this embodiment, the metal layer 19 is formed in one simultaneously with the wirings 11a and 12a using MAM.

The insulating layer 18b is formed on the insulating substrate 6 in which the shielding layer 7, the lower transparent electric conductive layer 15a, and the metal layer 19 are formed. The insulating layer 18b includes a contact hole 18c facing the metal layer 19. For this reason, the lower transparent electric conductive layer 15a is completely covered with the metal layer 19 and the insulating layer 18b. The metal layer 19 is covered with the insulating layer 18b except for the region facing the contact hole 18c. The insulating layer 18b is formed by an organic insulating material. In this embodiment, the insulating layer 18b is formed simultaneously with the insulating layer 18a using the organic insulating material.

The upper transparent electric conductive layer 15b is formed on the insulating layer 18b. The upper transparent electric conductive layer 15b is formed in the shape of a rectangle. The upper transparent electric conductive layer 15b is connected to the metal layer 19 through the contact hole 18c. The upper transparent electric conductive layer 15b is formed using ITO, etc. In this embodiment, the upper transparent electric conductive layer 15b is formed using ITO simultaneously with the first detection electrode 11, the second detection electrode 12, and the connection wiring 17. Moreover, the upper transparent electric conductive layer 15b also functions as a protection layer which controls oxidization of the metal layer 19.

In the portion of the pad, in which a connection area of the FPC4 contacts the pad “p”, the lower transparent electric conductive layer 15a, the metal layer 19, and the upper transparent electric conductive layer 15b overlap each other. As mentioned above, the metal layer 19 is formed by sandwiching aluminum system metal whose surface is very easily oxidized with a barrier metal Mo which is hard to be oxidized. For this reason, the metal layer 19 can contact with the lower layer transparent electric conductive layer 15a and the upper transparent electric conductive layer 15b with good ohmic contact. The metal layer 19 may be formed by sandwiching the metal layer of an aluminum system with a barrier metal of chromium group elements other than Mo. Thereby, the same effect as above-mentioned effect can be acquired. In addition, the metal layer 19 may be formed using TAT. Herein, TAT is a metal layer of three-layer structure in the abbreviated name of Ti (titanium)/AL (aluminum)/Ti. The above-mentioned aluminum layer includes aluminum alloys, such as Al—Nd (aluminum neodymium system alloy).

In addition, when the barrier metal is not interposed between the metal layer of an aluminum system and the transparent electrode (ITO), oxidization occurs in the surface of the metal layer of the aluminum system. Accordingly, ohmic contact is not made between the metal layer of the aluminum system and the transparent electrode (ITO).

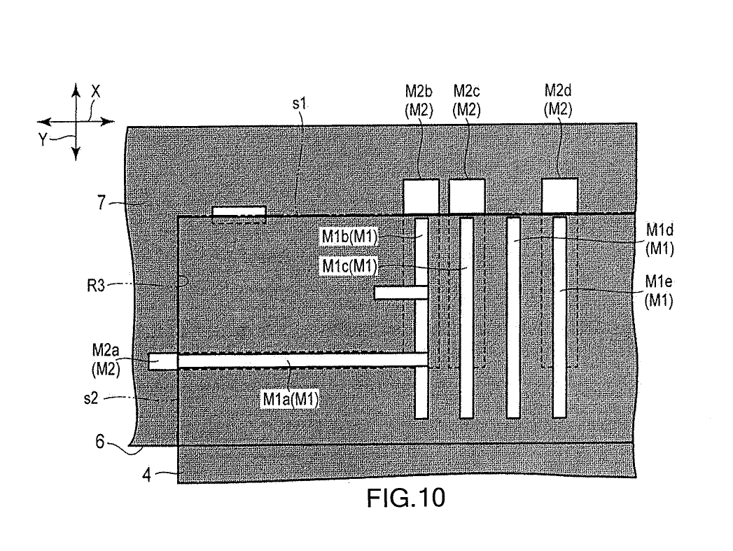

As shown in FIG. 4 and FIG. 10, the alignment pattern M2 is located in the outside of the input area R1, and provided on the shielding layer 7. The alignment pattern M2 is formed in an overlap region R3. Moreover, the alignment pattern M2 extends beyond the periphery of the overlap region R3 to outside of the overlap region R3, i.e., toward the input area R1.

The overlap region R3 has a long axis in the first direction X. In this embodiment, the alignment pattern M2 is formed in both ends (left and right) of the overlap region R3 in the X direction. The overlap region R3 is formed in the shape of a rectangle with a long end s1 and a short end s2. Some of the plurality of alignment patterns M2 extend to the outside of the overlap region R3 beyond the long end s1, and at least one of the plurality of alignment patterns M2 extends to the outside of the overlap region R3 beyond the short end s2.

If its attention is paid to the end on the left-hand side of the overlap region R3, the alignment pattern M2 includes alignment patterns M2a, M2b, M2c, and M2d. The alignment patterns M2a extends in the mutually different direction from that of the alignment patterns M2b, M2c, and M2d. The alignment pattern M2a is formed in the shape of a rectangle, and extends to the outside of the overlap region R3 beyond the short end s2 along the first direction X. The alignment patterns M2b, M2c, and M2d are formed also in the shape of a rectangle, and extend to the outside of the overlap region R3 beyond the long end s1 along the second direction Y. The alignment patterns M2b, M2c, and M2d are arranged with an interval in the first direction X, respectively.

The alignment pattern M2 is formed with a metal pattern, a transparent electric conductive pattern, or their complexes. When forming the alignment pattern M2 by the metal pattern, the alignment pattern M2 is simultaneously formed with the same material as the metal layer 19. When forming the alignment pattern M2 by the transparent electric conductive pattern, the alignment pattern M2 is simultaneously formed with the same material as the upper transparent electric conductive layer 15b. When forming the alignment pattern M2 with the complex of the metal pattern and the transparent electric conductive pattern, the alignment pattern M2 is simultaneously formed with the same material as the metal layer 19 and the upper transparent electric conductive layer 15b.

In this embodiment, the alignment pattern M2 is formed of the metal pattern. As mentioned above, in any cases, the alignment pattern M2 can be formed with the same material as the pad group PG.

As shown in FIG. 1 and FIG. 10, the FPC4 has a pad group which is not illustrated and a plurality of wirings connected to the pad group. The terminal area (pad group) of the FPC4 is put on the overlap region R3 in the insulating substrate 6. The FPC4 is not completely transparent.

Moreover, the FPC4 has an alignment pattern M1. The alignment pattern M1 is formed so that visual recognition is possible from the exterior of the FPC4. The alignment pattern M1 is also put on the overlap region R3 in the insulating substrate 6. The alignment pattern M1 and the alignment pattern M2 are used as a mark for alignment between the pad group PG in the insulating substrate 6 and the pad group of the FPC4.

The terminal area of the FPC4 is mechanically connected to the overlap region R3 in the insulating substrate 6. The pad group of the FPC4 is electrically connected to the pad group PG in the substrate 6. For example, the terminal area of the FPC4 is bonded to the overlap region R3 in the insulating substrate 6 by thermo-compression bonding using thermosetting type electric conductive adhesives which is not illustrated.

The first wiring W1 (the first detection electrode 11) and the second wiring W2 (the second detection electrode 12) are connected with external electronic components through the pad group PG and the FPC4. The above-mentioned electronic component can acquire input position information (input position coordinate) by sensing change of the electrostatic capacitance in the first wiring W1 and the second wiring W2 through the FPC4.

In the state where the FPC is mechanically and electrically connected with the touch panel 13, if its attention is paid to an angle portion on the upper left side of the FPC4, the alignment pattern M1 has alignment patterns M1a, M1b, M1c, M1d, and M1e. The alignment patterns M1a extends in a mutually different direction from that of the alignment patterns M1b, M1c, M1d and M1e.

The alignment pattern M1a is linearly formed extending along the first direction X. The alignment pattern M1a overlaps with the alignment pattern M2a. In this embodiment, the width (the length in the second direction Y) of the alignment pattern M1a is narrower than the width (the length in the second direction Y) of the alignment pattern M2a. For this reason, the alignment pattern M1a can be completely overlapped with the alignment pattern M2a.

The alignment patterns M1b, M1c, M1d, and M1e are linearly formed extending along the second direction Y. The alignment pattern M1b overlaps with the alignment pattern M2b, the alignment pattern M1c overlaps with the alignment pattern M2c, and the alignment pattern M1e overlaps with the alignment pattern M2d, respectively.

In this embodiment, the width (the length in the first direction X) of the alignment patterns M1b, M1c, M1d and M1e is narrower than the width (the length in the first direction X) of the alignment patterns M2b, M2c and M2e. For this reason, the alignment patterns M1b, M1c and M1e can be completely overlapped with the alignment patterns M2b, M2c and M2d, respectively.

As shown in FIG. 1, the adhesion material 5 is located between the liquid crystal display panel 1 (display surface S) and the touch panel 3. A transparent material is also used for the adhesion material 5. The adhesion material 5 attaches the touch panel 3 on the liquid crystal display panel 1. As the adhesion material 5, the material of an ultraviolet curing type or a thermosetting type is used.

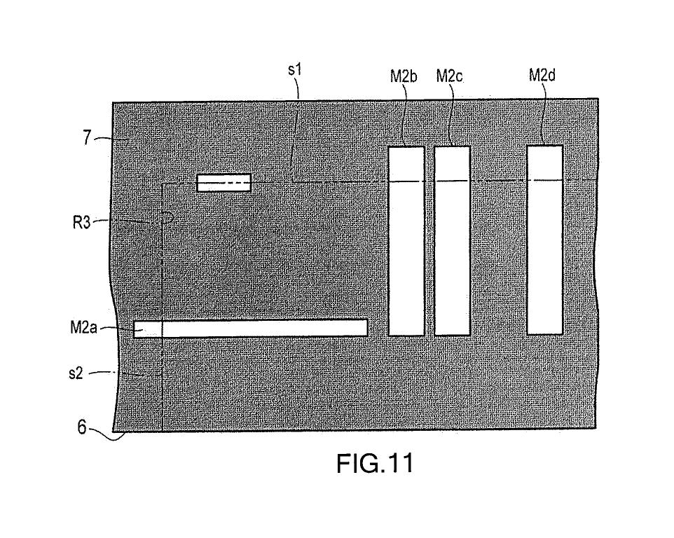

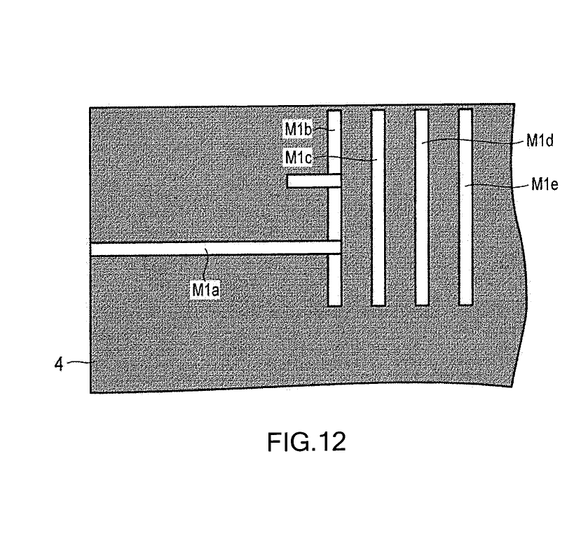

Next, a connection method is explained for connecting the FPC4 to the touch panel 3 which is a portion of production method (manufacturing process) of the liquid crystal display device. In a start of the connection method of the FPC4 to the touch panel 3, firstly, the touch panel 3 provided with the pad group PG and the alignment pattern M2 is prepared as shown in FIG. 11. As shown in FIG. 12, the FPC4 with the alignment pattern M1 is also prepared.

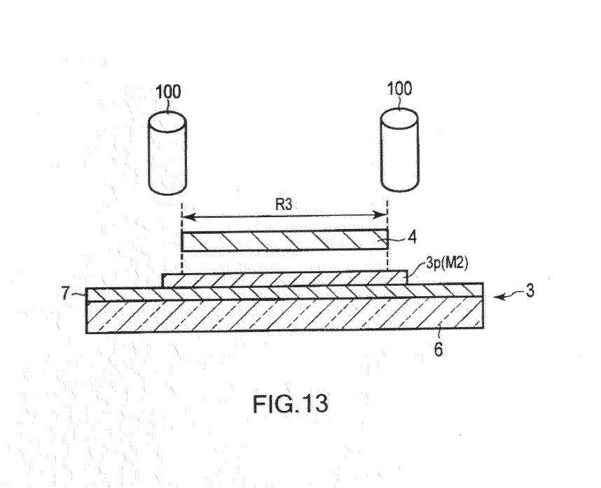

Next, as shown in FIGS. 11, 12 and 13, a camera 100 is set above the pattern 3p (the alignment pattern M2, pad group PG) in the touch panel 3, and both of the right and left ends of the overlap region R3 in the touch panel 3 are zoomed and taken a picture using the camera 100. Then, the FPC4 is made to counter the overlap region R3 in the touch panel 3. After that, the picture (video) taken with the camera 100 is viewed, and shifted portions between the alignment pattern M1 and the alignment pattern M2 are checked. The position of the FPC4 is adjusted, and then the alignment pattern M1 is overlapped with the alignment pattern M2.

As mentioned above, when the alignment pattern M1 and the alignment pattern M2 serve as an alignment mark, the alignment of the FPC4 to the touch panel 3 are performed. Thereby, the alignment between the pad group PG in the insulating substrate 6 and the pad group of the FPC4 can be performed.

Then, the FPC4 is bonded to the overlap region R3 in the touch panel 3 by thermo-compression bonding using thermosetting type electric conductive adhesion material. Also in this case, how the alignment pattern M1 and the alignment pattern M2 overlap is checked. Thereby, the FPC4 is mechanically and electrically connected to the touch panel 3, and the connection method of the FPC4 to the touch panel 3 is completed.

In the touch panel 3 and the liquid crystal display device constituted as mentioned above according to this embodiment, the touch panel 3 is equipped with the pad group PG and the alignment pattern M2. The pad group PG is provided in the overlap region R3 which is overlapped with the FPC4. The alignment pattern M2 extends to the outside of the overlap region R3 from its periphery.

The alignment between the FPC4 and the touch panel 3 is performed by visual recognition. By the way, the alignment pattern M2 cannot be visually recognized from the insulating substrate 6 side by the shielding layer 7. For this reason, when connecting the FPC4 to the touch panel 3, the camera 100 is set above the alignment pattern M2. Thereby, the alignment pattern M2 can be visually recognized, without being interrupted by the shielding layer 7.

However, as mentioned above, since the FPC4 is not completely transparent, it is difficult to visually recognize the alignment pattern M2 through the FPC4. Then, in this embodiment, the alignment pattern M2 is formed so that the alignment pattern M2 may extend to the outside of the overlap region R3. Thereby, it becomes possible to visually recognize the shift of the FPC4 using the alignment pattern M1 in the FPC 4 and the alignment pattern M2 in the insulating substrate 6.

That is, the alignment pattern M1 is formed so as to be visually recognized from the outside of the FPC4. The portion in the alignment pattern M2 located in the outside of the FPC4 is exposed. In addition, since the alignment pattern M2 is formed of the metal pattern according to this embodiment, the light reflected by the alignment pattern M2 is visually recognized. Thereby, even in the case where the FPC4 is connected with the pad group PG formed on the shielding layer 7, the alignment between the pad group PG in the insulating substrate 6 and the pad group of the FPC4 can be performed satisfactorily.

As mentioned above, it becomes possible to supply the touch panel 3 and the liquid crystal display device equipped with the touch panel 3, which can secure stable electrical connection with the FPC4.

While certain embodiments have been described, these embodiments have been presented by way of embodiment only, and are not intended to limit the scope of the inventions. In practice, the structural elements can be modified without departing from the spirit of the invention. Various embodiments can be made by properly combining the structural elements disclosed in the embodiments. For embodiment, some structural elements may be omitted from all the structural elements disclosed in the embodiments. Furthermore, the structural elements in different embodiments may properly be combined. The accompanying claims and their equivalents are intended to cover such forms or modifications as would fall with the scope and spirit of the inventions.

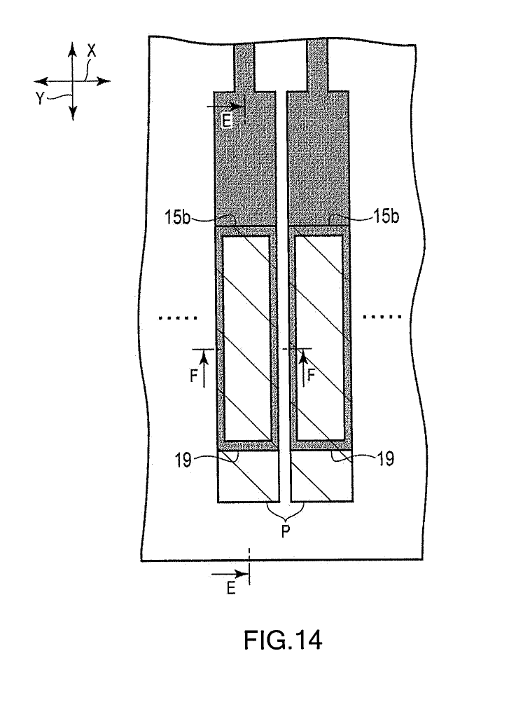

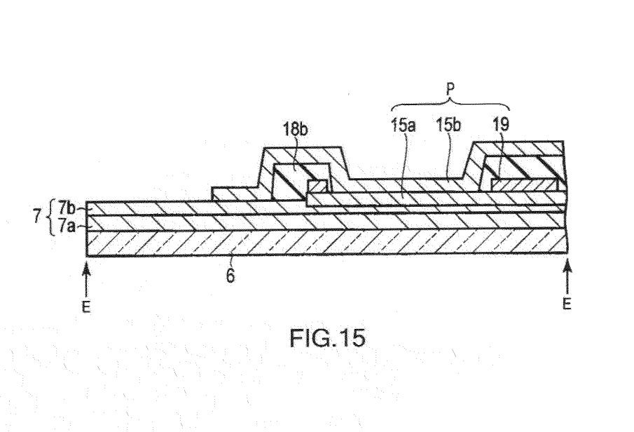

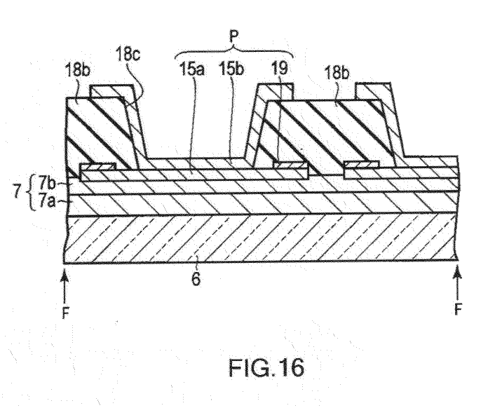

As shown in FIGS. 14, 15 and 16, the pad “p” may be formed using the metal layer 19, in which the barrier metal is provided only one side of the metal layer of an aluminum system. Thereby, compared with the case where MAM is used for forming the metal layer 19, a manufacturing cost can be reduced, for example. The metal layer 19 is formed on the rectangular lower transparent electric conductive layer 15a in a frame shape. The metal layer 19 includes the barrier layer (bottom barrier metal layer) only on the side contacting to the lower transparent electric conductive layer 15a.

The insulating layer 18b is provided with the contact hole 18c which counters the lower transparent electric conductive layer 15a. For this reason, the metal layer 19 is completely covered with the insulating layer 18b. The upper transparent electric conductive layer 15b is formed on the insulating layer 18b. The upper transparent electric conductive layer 15b is formed in the shape of a rectangle, and connected to the lower layer transparent electric conductive layer 15a through the contact hole 18c. In the portion where the pad “p” contacts to the terminal area of the FPC4, the lower transparent electric conductive layer 15a and the upper transparent electric conductive layer 15b overlap.

Even if the metal layer 19 is formed with the above aluminum layer, the pad “p” can be formed by contacting the upper transparent electric conductive layer 15b to the lower transparent electric conductive layer 15a, without contacting the upper transparent electric conductive layer 15b to the metal layer 19. Thereby, the pad “p” which does not become the fault at the time of thermo compression bonding can be obtained. The above-mentioned metal layer 19 may be formed in the U shape in which the lower end portion is opened, for example.

The form of the alignment pattern M2 can be modified variously. For example, the alignment pattern M2 may be formed of a metal layer in a frame shape or U shape in which the lower end portion is opened.

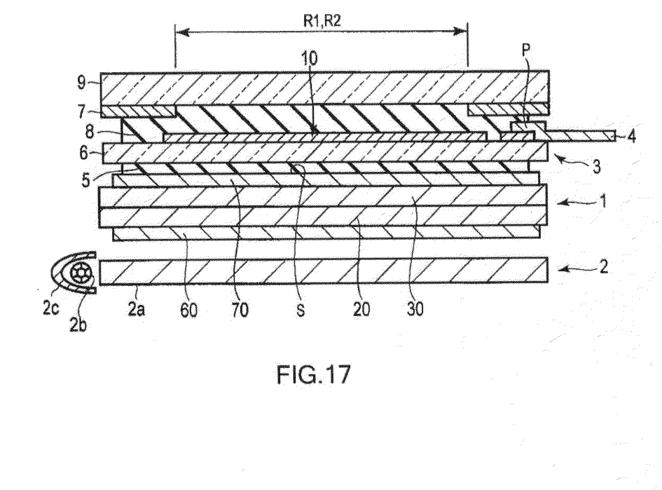

The embodiments of the present invention are applicable not only to the above-mentioned liquid crystal display device but various kinds of liquid crystal display devices. For example, as shown in FIG. 17, the liquid crystal display device may be further equipped with an insulating substrate 9 and an adhesion material 8. The shielding layer 7 is formed on the insulating substrate 9, not on the insulating substrate 6. The insulating substrate 6 does not function as a decorative plate.

The insulating substrate 9 counters the sensor module 10 of the touch panel 3. The insulating substrate 9 is formed in a flat rectangular shape. The insulating substrate 9 functions as a decorative plate. The appearance of the liquid crystal display device is decorated with the insulating substrate 9. The insulating substrate 9 can be formed of glass or transparent insulation material, such as an acrylic resin.

The adhesion material 8 is arranged between the insulating substrate 9 and the touch panel 3. A transparent material is used for the adhesion material 8. The adhesion material 8 attaches the insulating substrate 9 on the touch panel 3. As the adhesion material 8, the material of an ultraviolet curing type or a thermosetting type can be used.

Also according to the embodiment shown in FIG. 17, the same effect as that in the embodiment shown in FIG. 1 can be acquired using the alignment pattern M2 extending to the outside of the overlap region R3. Moreover, as shown in FIG. 17, the embodiment of the present invention is not limited to the structure in which the pad “p” and the alignment pattern M2 are formed on the shielding layer 7. When the pad “p” and the alignment pattern M2 do not need to be formed on the shielding layer 7, the alignment pattern M2 may be formed by a transparent electric conductive pattern. Since the outline of the alignment pattern M2 can be visually recognized, the position of the alignment pattern M2 is recognized.

The alignment pattern M1 may include at least one alignment pattern extending in the first direction X, and at least one alignment pattern extending in the second direction Y. Similarly, the alignment pattern M2 may include at least one alignment pattern extending in the first direction X, and at least one alignment pattern extending in the second direction Y.

In the above embodiments, the alignment between the pad group PG in the insulating substrate 6 and the pad group of the FPC4 is performed by making the alignment pattern M1 overlap with the alignment pattern M2. However, the alignment pattern M1 and the alignment pattern M2 may serve only as an alignment mark. For this reason, it is also possible to perform the alignment between the pad group PG in the insulating substrate 6 and the pad group of the FPC4, for example, by other technique, such as to put the alignment pattern M1 on the alignment pattern M2. Moreover, the forms of the alignment pattern M1 and the alignment pattern M2 are not limited to the above embodiments, and can be changed variously.

The electronic component according to the embodiment of the present invention is not limited to the touch panel 3, and can be modified variously. Furthermore, the electronic device according to the embodiment of the present invention is not limited to a liquid crystal display device, either, and can be modified variously. The display panel according to the embodiment of the present invention is not limited to the liquid crystal display panel, and can be modified variously. For example, the embodiment is applicable to an organic EL (electroluminescent) display panel.

What is claimed is:

1. An electronic component comprising:
a substrate;
a shielding layer formed on the substrate;
a wiring substrate connected to the substrate;
a pad group formed on an overlap region on which the wiring substrate is arranged on the substrate;
a first alignment pattern formed on the substrate and extending to outside of the overlap region beyond a peripheral portion of the overlap region;
a second alignment pattern formed on the substrate and extending to outside of the overlap region beyond the peripheral portion of the overlap region;
wherein the pad group, the first and second alignment patterns are formed on the shielding layer, and
the first alignment pattern extends in a different direction from the direction of the second alignment pattern.

2. The electronic component according to claim 1, wherein the first and second alignment patterns are provided at end portions of the overlap region.

3. The electronic component according to claim 2, wherein the overlap region is formed in a rectangular shape with a long end and a short end,
the first pattern extends to outside of the overlap region beyond the long end, and
the second pattern extends to outside of the overlap region beyond the short end.

4. The electronic component according to claim 1, wherein the first and second alignment patterns are formed of the same material as the pad group.

5. The electronic component according to claim 4, wherein the first and second alignment patterns are formed of a metal pattern, a transparent conductive pattern or a complex of the metal pattern and the transparent pattern.

6. A touch panel, comprising:
an insulating substrate including an input area and a peripheral area located adjacent to the input area;
a shielding layer formed on the peripheral area;
a wiring substrate connected to the substrate;
an input device arranged in the input area and including a plurality of detection electrodes arranged in first and second directions orthogonally crossing each other in a matrix shape;
a pad group formed on an overlap region in the peripheral area on which the wiring substrate is arranged, and connected with the detection electrodes through connection wirings;
an adhesive material to attach the wiring substrate and the insulating substrate;
a first alignment pattern formed on the insulating substrate and extending to outside of the overlap region beyond the peripheral portion of the overlap region;
a second alignment pattern formed on the insulating substrate and extending to outside of the overlap region beyond the peripheral portion of the overlap region; and
a third alignment pattern formed on the wiring substrate,
wherein the pad group, the first and second alignment patterns are formed on the shielding layer,
the first alignment pattern extends in a different direction from the direction of the second alignment pattern, and
the third alignment pattern is arranged on the first and second alignment patterns.

7. The touch sensor according to claim 6, wherein
the overlap region is formed in a rectangular shape with a long end and a short end,
the first pattern extends to outside of the overlap region beyond the long end, and
the second pattern extends to outside of the overlap region beyond the short end.

8. The electronic component according to claim 6, wherein the first and second alignment patterns are formed of the same material as the pad group.

9. The electronic component according to claim 8, wherein the first and second alignment patterns are formed of a metal pattern, a transparent conductive pattern or a complex of the metal pattern and the transparent pattern.

10. A liquid crystal display device comprising:
a touch panel including;
an insulating substrate including an input area and a peripheral area located adjacent to the input area;
a shielding layer formed on the peripheral area;
a wiring substrate connected to the substrate;
an input device arranged in the input area and including a plurality of detection electrodes arranged in first and second directions orthogonally crossing each other in a matrix shape;
a pad group formed on an overlap region in the peripheral area on which the wiring substrate is arranged, and connected with the detection electrodes through connection wirings;
an adhesive material to attach the wiring substrate and the insulating substrate,
a first alignment pattern formed on the insulating substrate and extending to outside of the overlap region beyond the peripheral portion of the overlap region;
a second alignment pattern formed on the insulating substrate and extending to outside of the overlap region beyond the peripheral portion of the overlap region; and
a third alignment pattern formed on the wiring substrate;
wherein the pad group, the first and second alignment patterns are formed on the shielding layer,
the first alignment pattern extends in a different direction from the direction of the second alignment pattern, and
the third alignment pattern is arranged on the first and second alignment patterns,
a liquid crystal display panel including a display area arranged facing the input area of the touch panel, wherein
the touch panel is attached to the liquid crystal panel using an adhesive material.

11. The liquid crystal display device according to claim 10, wherein
the overlap region is formed in a rectangular shape with along an end and a short end,
the first pattern extends to outside of the overlap region beyond the long end, and
the second pattern extends to outside of the overlap region beyond the short end.

12. The liquid crystal display device according to claim 10, wherein the first and second alignment patterns are formed of the same material as the pad group.

13. The liquid crystal display device according to claim 12, wherein the first and second alignment patterns are formed of a metal pattern, a transparent conductive pattern or a complex of the metal pattern and the transparent pattern.

14. A method of manufacturing a touch panel, comprising the steps:
preparing an insulating substrate including an input area and a peripheral area located adjacent to the input area;
forming a shielding layer formed on the peripheral area;
forming an input device arranged in the input area and including a plurality of detection electrodes arranged in first and second directions orthogonally crossing each other in a matrix shape;
forming a pad group on an overlap region in the peripheral area on which a wiring substrate is arranged, the pad group being connected with the detection electrodes through connection wirings;
forming a first alignment pattern on the insulating substrate and extending to outside of the overlap region beyond the peripheral portion of the overlap region;
forming a second alignment pattern on the insulating substrate and extending to outside of the overlap region beyond the peripheral portion of the overlap region;
forming a third alignment pattern on the wiring substrate;
performing alignment of the first and second alignment patterns and the third alignment pattern by visually adjusting shift among the first second and third alignment patterns from above the first and second alignment patterns; and
attaching the insulating substrate to the wiring substrate by overlapping the first and second alignment patterns with the third alignment pattern using an adhesive,
wherein the first alignment pattern extends in a different direction from the direction of the second alignment pattern, and the third alignment pattern is arranged on the first and second alignment patterns.

15. The method of manufacturing a touch panel according to claim 14, wherein the overlap region is formed in a rectangular shape with a long end and a short end, the first pattern extends to outside of the overlap region beyond the long end, and the second pattern extends to outside of the overlap region beyond the short end.

16. The method of manufacturing a touch panel according to claim 15, wherein the alignment pattern is formed of a metal pattern, a transparent conductive pattern or a complex of the metal pattern and the transparent pattern.
